(19) United States
(12) Patent Application Publication
(10) Pub. No.: US 2023/0291178 A1
(43) Pub. Date: Sep. 14, 2023

(54) LASER STRUCTURE AND METHOD FOR FABRICATING LASER STRUCTURE

(71) Applicant: Shenzhen Banyan Photonics Technologies Co., Ltd., Shenzhen (CN)

(72) Inventors: Fang WU, Shenzhen (CA); Yongbo TANG, Shenzhen (CN); Christopher D. Watson, Shenzhen (GB); Kirill Y. Pimenov, Shenzhen (CA); Yury Logvin, Shenzhen (CA)

(73) Assignee: Shenzhen Banyan Photonics Technologies Co., Ltd., Shenzhen (CN)

(21) Appl. No.: 18/117,509

(22) Filed: Mar. 6, 2023

(30) Foreign Application Priority Data
Mar. 8, 2022 (CN) 202210228849.9

(51) Int. Cl. H01S 5/12; H01S 5/042

(52) U.S. Cl. CPC H01S 5/1231; H01S 5/04256; H01S 5/34

(57) ABSTRACT

Disclosed are a laser structure and a method for fabricating the laser structure. The method includes: providing an epitaxial structure, the epitaxial structure including a substrate, a first doped dielectric layer, a multiple quantum well active layer and a ridge-shaped doped dielectric layer stacked in sequence; forming a grating structure on the ridge-shaped doped dielectric layer and forming a reflective surface on one end of the grating structure, the reflective surface and the grating structure are defined by a same lithography mask, and the mask is protected in a semiconductor etching process selectively, ensuring that relative positions of the reflective surface and the grating structure are not changed, so that light reflected from the reflective surface back to laser cavity has a predetermined phase defined by design, therefore improves performance and stability of the laser, reduces complexity and cost of the fabrication process, and increases yield and reliability.

### CROSS-REFERENCE TO RELATED APPLICATIONS

This application claims priority to Chinese patent application No. 2022102288499 filed with the Chinese Patent Office on Mar. 8, 2022, entitled “LASER STRUCTURE FABRICATION METHOD AND LASER STRUCTURE”, which is incorporated herein by reference in its entirety.

### TECHNICAL FIELD

The application relates to the field of semiconductor laser fabricating, and in particular, to a laser structure and a method for fabricating a laser structure.

### BACKGROUND

Distributed feedback (DFB) semiconductor lasers are widely deployed in optical communication systems due to their dynamic single mode, compact size, integration capability and reliable light sources.

Basic elements of a laser consist of three parts: a gain medium, a cavity with a feedback mechanism, and an energy input. A distributed feedback laser has two mechanisms to achieve feedback, which are periodic refractive index modulation and periodic gain (loss) modulation.

### SUMMARY

Based on the above-mentioned problems in the background technology, it is necessary to provide a laser structure and a method for fabricating a laser structure, which can effectively improve the performance and stability of semiconductor lasers, reduce the complexity and manufacturing cost of the fabrication process, and improve the yield and reliability.

In order to achieve the above and other relevant goals, one aspect of the present application provides a method for fabricating a laser structure, including: providing an epitaxial structure, the epitaxial structure comprising a substrate, a first doped dielectric layer, a multiple quantum well active layer and a ridge-shaped doped dielectric layer, which are stacked in sequence; forming a grating structure on the ridge-shaped doped dielectric layer, and forming a reflective surface at one end of the grating structure, the grating structure comprising a plurality of grating grooves periodically spaced along a waveguide direction of the laser and preset conductive regions defined by the grating grooves, a light-transmitting insulating layer covering at least sidewall of the grating grooves being formed in each grating groove; light reflected back to a laser cavity by the reflective surface having a preset phase; and forming a top electrode layer, the top electrode layer forming an ohmic contact with at least a top surface of each of the preset conductive regions, enabling carriers injected through the top electrode layer to flow through the preset conductive regions and the ridge-shaped doped dielectric layer under the grating grooves in turn, and then diffuse laterally to the multiple quantum well active layer to form a carrier distribution region for providing pumping.

In an embodiment, the step of forming the grating structure on the ridge-shaped doped dielectric layer and the reflective surface at one end of the grating structure includes: forming a first masking layer on an upper surface of the ridge-shaped doped dielectric layer, the first masking layer includes first opening patterns and a second opening pattern formed by lithography for removing part of the first masking layer, the first opening patterns are configured to define a position and a shape of each of the grating grooves, the second opening patterns are configured to define a position and a shape of the reflective surface with a preset phase; forming a second masking layer, the second masking layer covers at least the second opening pattern with the first opening patterns exposed; forming the grating grooves by removing part of the first masking layer and part of the ridge-shaped doped dielectric layer; forming a light-transmitting insulating material layer, the light-transmitting insulating material layer fills each of the grating grooves and covers an upper surface of the second masking layer; removing part of the light-transmitting insulating material layer, part of the second mask layer, part of the ridge-shaped doped dielectric layer, part of the multiple quantum well active layer and part of the first doped dielectric layer to form the reflective surface; and removing the light-transmitting insulating material layer located on top of the grating grooves to form the grating structure, and a remaining part of the light-transmitting insulating material layer constituting a light-transmitting insulating layer.

In an embodiment, forming the grating structure on the ridge-shaped doped dielectric layer and forming the reflective surface at one end of the grating structure includes: forming a first masking layer on an upper surface of the ridge-shaped doped dielectric layer, the first masking layer includes first opening patterns and a second opening pattern, the first opening patters and the second opening patter are formed by removing part of the first masking layer by lithography, the first opening patterns are configured to define a position and a shape of each of the grating grooves, and the second opening pattern is configured to define a position and a shape of the reflective surface with the preset phase; forming a second masking layer, the second masking layer covers at least the second opening pattern and exposes the first opening patterns and part of the upper surface of the ridge-shaped doped dielectric layer; removing part of the first masking layer and part of the ridge-shaped doped dielectric layer to form the grating grooves; forming a light-transmitting insulating material layer, the light-transmitting insulating material layer fills the grating grooves and covers an upper surface of the second mask layer; removing the light-transmitting insulating material layer located on top of the grating grooves to form the grating structure, and a remaining part of the light-transmitting insulating material layer constituting a light-transmitting insulating layer; forming a top electrode layer, the top electrode layer at least covering the top surface of the preset conductive regions and forming the ohmic contacts with the preset conductive regions; forming a third masking layer covering at least a top of the top electrode layer; and removing part of the light-transmitting insulating material layer, part of the second masking layer, part of the ridge-shaped doped dielectric layer, part of the multiple quantum well active layer and part of the first doped dielectric layer, to form the reflective surface.

In an embodiment, after forming the light-transmitting insulating material layer, the method further includes: removing the light-transmitting insulating material layer located on top of the grating grooves to form the grating structure, and the remaining part of the light-transmitting insulating material layer constituting the light-transmitting insulating layer; forming the top electrode layer, the top electrode layer at least covering the top surface of the preset conductive regions and forming the ohmic contacts with the preset conductive regions; forming the third masking layer covering at least a top of the top electrode layer; and removing part of the light-transmitting insulating material layer, part of the second masking layer, part of the ridge-shaped doped dielectric layer, part of the multiple quantum well active layer and part of the first doped dielectric layer, to form the reflective surface.

In an embodiment, the etching rate of the second masking layer is different from that of the first masking layer. The second masking layer is used to protect the second opening pattern from being damaged by the process of etching the grating grooves.

In an embodiment, the step of forming the grating structure on the ridge-shaped doped dielectric layer and forming the reflective surface at one end of the grating structure include: forming a first masking layer on an upper surface of the ridge-shaped doped dielectric layer, the first masking layer includes first opening patterns and a second opening pattern, the first opening patterns and the second opening pattern being formed by removing part of the first masking layer by lithography, the first opening patterns are configured define a position and a shape of each of the grating grooves, and the second opening pattern is configured to define a position and a shape of the reflective surface with the preset phase; forming a fourth masking layer, the fourth masking layer covers at least the first opening patterns with the second opening patterns being exposed; removing part of the ridge-shaped doped dielectric layer, part of the multiple quantum well active layer and part of the first doped dielectric layer to form the reflective surface; removing the fourth masking layer to expose the first opening patterns, and etching to remove part of the first masking layer and par of the ridge-shaped doped dielectric layer based on the first opening patterns to form the grating grooves; and forming a light-transmitting insulating layer in at least the grating grooves to form the grating structure.

In an embodiment, the etching rates of the fourth masking layer and the first masking layer are different.

In an embodiment, before forming the grating structure on the ridge-shaped doped dielectric layer and forming the reflective surface at one end of the grating structure, the method further includes: forming an electrical contact layer on the top of the ridge-shaped doped dielectric layer, and forming the top electrode layer on the top of the electrical contact layer, the electrical contact layer enables the top electrode layer to form an effective electrical connection with the preset conductive regions.

In an embodiment, before forming the grating structure and the reflective surface, or between forming the grating structure and forming the reflective surface, or after forming the grating structure and the reflective surface, the method further includes: performing at least one laser waveguide definition process on an obtained structure.

In an embodiment, after forming the reflective surface, the method further includes: forming a reflective film on the reflective surface.

In an embodiment, the material for forming the reflective film includes at least one of high-reflection material and anti-reflection material.

Another aspect of the application provides a laser structure fabricated using the methods for fabricating the laser structure described in any of the embodiments of the present application.

### BRIEF DESCRIPTION OF THE DRAWINGS

To better describe and illustrate the embodiments and/or examples of the present application, one or more of the enclosed drawings can be referenced. The additional details or examples used to describe the drawings should not be considered to limit the scope of any of the present application, the embodiments and/or examples of the present application, and the best mode of the application as presently understood.

FIG. 1 shows a schematic flowchart of a method for fabricating a laser structure according to an embodiment of the present application.

FIG. 2 shows a schematic flowchart of a method for fabricating a laser structure according to another embodiment of the present application.

FIG. 3a shows a schematic flowchart of a method for fabricating a laser structure according to yet another embodiment of the present application.

FIG. 3b shows a schematic flowchart of a method for fabricating a laser structure according to another embodiment of the present application.

FIGS. 4-13 are schematic diagrams showing cross-sectional structures obtained in different steps according to an embodiment of the present application.

FIG. 14 is a schematic diagram of a refractive index coupling intensity curve of a laser structure according to an embodiment of the present application.

FIGS. 15-16 are schematic diagrams showing modulation curves of injection current amplitude versus carrier distribution of a laser structure in different embodiments of the present application.

### DETAILED DESCRIPTION OF THE EMBODIMENTS OF THE APPLICATION

To better understand the application, the application will be described comprehensively with drawings. The drawings show the preferred embodiments of the present application. However, the application may be implemented in many different forms and is not limited to the embodiments described herein. Rather, these embodiments are provided so that this application will be thorough and complete.

Unless otherwise defined, all technical and scientific terms used herein have the same meaning as commonly understood by one of ordinary skill in the technical field to which the present application belongs. The terms used herein are for the purpose of describing specific embodiments only and are not intended to limit the application. As used herein, the term “and/or” includes all combinations of one or more of the listed items.

It should be understood that when an element or layer is referred to as being “on,” “adjacent to,” “connected to,” or “coupled to” other elements or layers, it may be directly on, adjacent, connected or coupled to other elements or layers, or be present intermediately in elements or layers. In contrast, when an element is referred to as being “directly on,” “directly adjacent to,” “directly connected to,” or “directly coupled to” other elements or layers, there are no intermediary elements or layers present. Although the terms first, second, third, etc. may be used to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the guidelines of the application.

Spatial relational terms such as “under”, “below”, “beneath”, “underneath”, “above”, “on top of”, etc., may be used herein for convenience of describing the relationship of one element or feature to other elements or features shown in the drawings. In addition to the orientation shown in the drawings, the spatial relation terms are harmonized with different orientations of the device in use. For example, if the device in the drawings is turned over, then elements or features described as “below” or “beneath” or “underneath” other elements or features would then be oriented “above” the other elements or features. Thus, the exemplary terms “below” and “under” may encompass both an orientation of above and below. The device may be oriented in other way (rotated 90 degrees or at other orientations) and the spatial description used herein should be interpreted accordingly.

The terminology used herein is for the purpose of describing particular embodiments only and is not intended to limit the application. As used herein, the singular forms “a,” “an,” and “the/this” are intended to include the plural forms as well, unless the context clearly dictates otherwise. It is also to be understood that the terms “compose” and/or “include”, used in this description, identify the presence of stated features, integers, steps, operations, elements and/or components, but do not exclude the presence or addition of one or more other of features, integers, steps, operations, elements, parts and/or groups. As used herein, the term “and/or” includes all combinations of the listed items.

Embodiments (and intermediate structures) of the application are described herein with schematic and cross-section illustration references. As such, variations of the shapes shown due to for example, manufacturing techniques and/or tolerances, may be expected. Thus, embodiments of the application should not be limited to the particular shapes of the regions shown herein, but include shape deviations due to, for example, manufacturing. The regions shown in the drawings are illustrative, they are not intended to show the actual shapes of the regions of the device and are not intended to limit the scope of this application.

The “transmittance” mentioned in this application means that the transmittance of the light excited by the laser is greater than or equal to 75%.

The distributed feedback laser adopts a periodic grating structure along the longitudinal direction of the active cavity to realize the periodic modulation of the effective refractive index of the active waveguide. Refractive index modulation is to select a laser wavelength near the Bragg wavelength by constructive interference of wavelengths through real part, imaginary part or complex number action. The Bragg wavelength λ_{B}=2Λneff/m, where Λ is a grating period, neff is an effective refractive index of the guided mode, and m is a grating order. The basic elements of a laser include three parts: the gain medium, the cavity with the feedback mechanism, and the energy input. There are two feedback mechanisms for the distributed feedback lasers: one is to form a periodic grating structure along the active medium in the longitudinal direction, the other is to use the effective refractive index of the active waveguide to introduce periodic modulation. This periodic modulation achieves the constructive interference in a specific wavelength range, centered at the Bragg wavelength. There are two degenerate resonant modes, which are symmetrically distributed on both sides of the Bragg wavelength. By adding additional structures such as reflective surfaces in the distributed feedback laser, a stable single-mode output of the distributed feedback laser can be achieved. It is well known that a continuous grating will have two longitudinal modes at equally spaced positions on both sides of the Bragg wavelength. In order to achieve a single-mode operation and improve the output power of the laser front-end surface, usually a highly reflective film will be coated at the back-end surface of the laser cavity and the front-end surface will be coated with an anti-reflective film. The phase reflected back to the laser cavity by the high-reflection film directly affects the performance of the laser. The precise control of the phase (i.e., the position of the high-reflection film relative to the grating) is very challenging. Uncontrolled phase will lead to issues such as costly test screening processes and low yields. Improving the yield and reliability of the distributed feedback semiconductor lasers and reducing the manufacturing cost is one of the technical challenges to be addressed urgently by the relevant scientists and engineers.

The application aims to provide a laser structure and a method for fabricating such a laser structure. The distance between the reflective surface and the end of the grating structure is determined by design and lithography, so that the phase of the light reflected back to the laser cavity is determined, which improves the performance and stability of the laser, reduces the complexity and the cost of the fabrication process, and improves its yield and reliability.

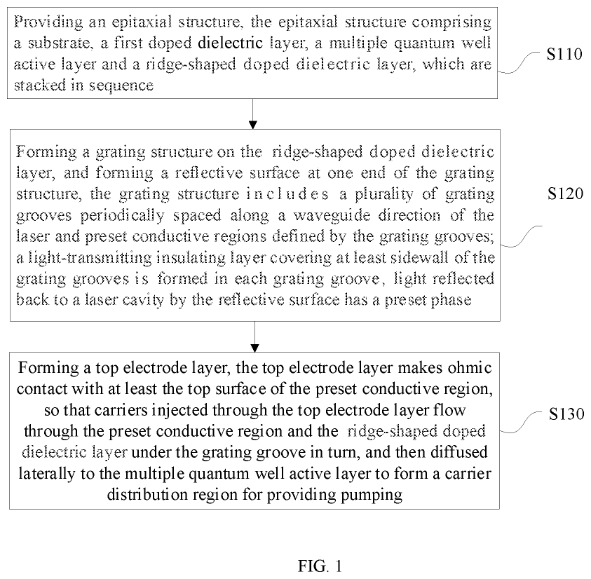

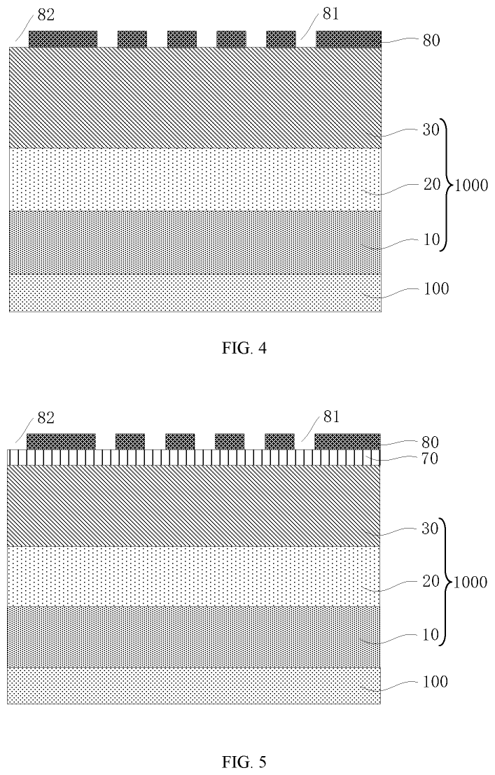

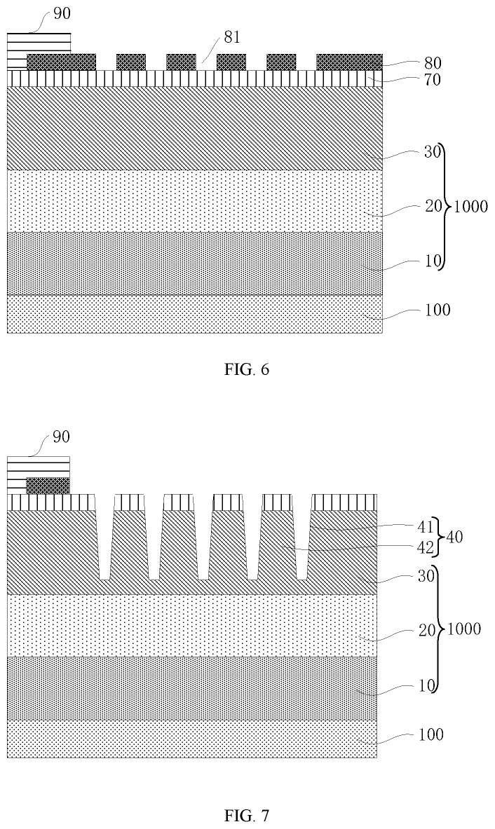

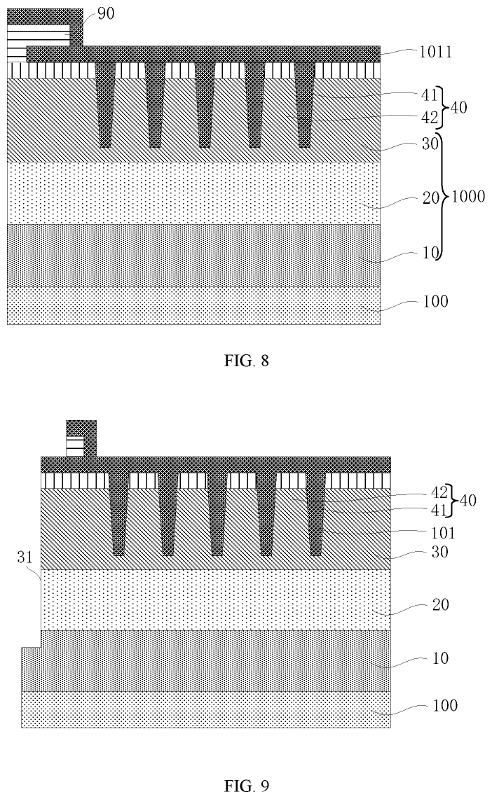

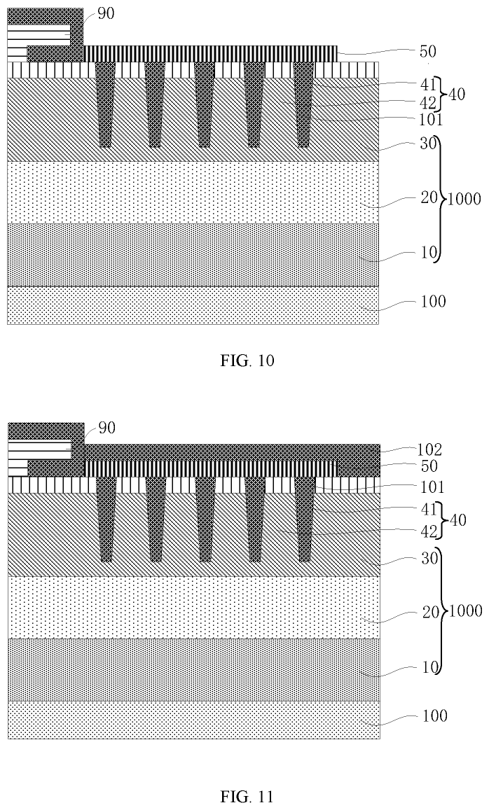

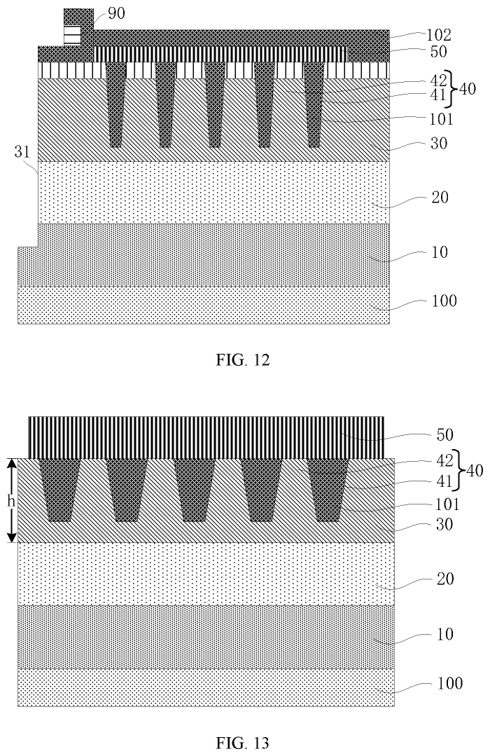

Referring to FIGS. 1-16, it should be noted that the drawings provided in this application are only to illustrate the basic concept of the application in a schematic way. Although the drawings only show the components related to the application rather than the number, the shape and the drawing dimension, the type, quantity and proportion of each component may be arbitrarily changed in actual implementation, and the component layout may also be more complicated.

Referring to FIG. 1, in an embodiment of the application, a method for fabricating a laser structure is provided, which includes the following steps.

At step S110, an epitaxial structure is provided, the epitaxial structure includes a substrate, a first doped dielectric layer, a multiple quantum well active layer and a ridge-shaped doped dielectric layer which are stacked in sequence.

At step S120, a grating structure is formed on the ridge-shaped doped dielectric layer and a reflective surface is formed at one end of the grating structure. The grating structure includes a plurality of grating grooves periodically spaced along the waveguide direction of the laser, and preset conductive regions defined by the grating grooves. A light-transmitting insulating layer covering at least the sidewall of the grating grooves is formed in the grating grooves. The light reflected back to the laser cavity by the reflective surface has a preset phase.

At step S130, a top electrode layer is formed, the top electrode layer makes ohmic contacts with at least the top surface of the preset conductive regions, so that carriers injected through the top electrode layer flow through the preset conductive regions and the ridge-shaped doped dielectric layer under the grating grooves in turn, and then diffused laterally to the multiple quantum well active layer to form a carrier distribution region for providing pumping.

Specifically, please continue to refer to FIG. 1, firstly, the grating structure including the plurality of grating grooves uniformly spaced along the waveguide direction of the laser and the preset conductive regions defined by the grating grooves is formed on the ridge-shaped doped dielectric layer. The grating grooves are electrical insulators, which restrict the flowing areas of the injected current. When a distance between the bottom of the grating groove and the multiple quantum well active layer is small, the diffusion of the injection current at the bottom of the grating groove is limited, which makes a carrier density along the grating groove in the direction of the laser cavity fluctuating periodically, producing some degree of gain modulation. Since the phase of the gain coupling in the present application coincides with the phase of the index coupling, the phase of the gain coupling and the phase of the index coupling will not cancel each other out, the intensity of the gain modulation and the refractive index modulation may be tailored by the shape, duty cycle and order of the grating grooves, which effectively improves the laser efficiency and performance. The reflective surface may be used to realize an asymmetric mirror feedback of the laser to break the degenerate mode and realize the stable single-mode output of the laser. Since the reflective surface in the present application is formed in a process of preparing the grating structure, the process steps introduced by the addition of the reflective surface are effectively reduced, the manufacturing cost of the laser structure is reduced, and the yield of the prepared laser structure is improved and reliability. In this embodiment, the carriers may be set to uniformly distributed in the region under different injection currents.

Since the grating structure includes the plurality of grating grooves distributed at uniform intervals along the waveguide direction of the laser and the preset conductive area defined by each grating groove, that is, the distribution of the grating grooves is periodic, a grating duty cycle of the grating structure is related to a gain modulation intensity of a ridge laser structure. The grating duty cycle is a ratio of an area of an orthographic projection of the preset conductive region between adjacent grating grooves on the upper surface of the first doped dielectric layer to the grating period. A grating order of the grating structure is related to the refractive index modulation intensity of the ridge laser structure. By establishing a corresponding relationship between the grating duty cycle of the grating structure and the gain modulation intensity of the ridge laser structure, the gain modulation intensity of the ridge laser structure may be adjusted by setting the grating duty cycle of the grating structure. By establishing a corresponding relationship between the granting order of the grating structure and the refractive index modulation intensity of the ridge laser structure, the refractive index modulation intensity may be adjusted by setting the grating order of the grating structure. Thus, the degree of freedom of the gain modulation intensity and/or the refractive index modulation intensity of the fabricated lasers is increased.

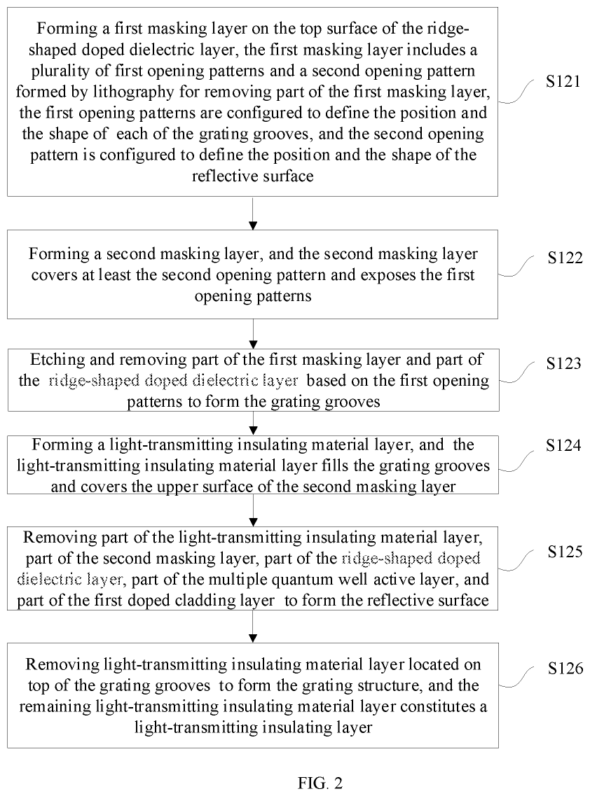

Referring to FIG. 2, in an embodiment of the application, the grating structure is formed on the ridge-shaped doped dielectric layer, and the reflective surface is formed on one end of the grating structure, and the reflective surface and the grating structure are formed by a same lithography step. However, the fabrication of other functional elements, such as the top electrode layer in this embodiment, may be inserted between the etching of the reflective surface and the etching of the grating structure. The grating structure formed on the ridge-shaped doped dielectric layer and the reflective surface formed on one end of the grating structure includes the following steps.

At step S121, a first masking layer is formed on the top surface of the ridge-shaped doped dielectric layer where the ridge is designed to be. The first masking layer includes a plurality of first opening patterns and a second opening pattern, the first opening patterns and the second opening patter are formed by lithography for removing part of the first masking layer. The first opening patterns are configured to define the position and the shape of each of the grating grooves, and the second opening pattern is configured to define the position and the shape of the reflective surface.

At step S122, a second masking layer is formed, and the second masking layer covers at least the second opening pattern and exposes the first opening patterns.

At step S123, part of the first masking layer and part of the ridge-shaped doped dielectric layer are etched and removed based on the first opening patterns to form the grating grooves.

At step S124, a light-transmitting insulating material layer is formed, and the light-transmitting insulating material layer fills the grating grooves and covers the upper surface of the second masking layer.

At step S125, part of the light-transmitting insulating material layer, part of the second masking layer, part of the ridge-shaped doped dielectric layer, part of the multiple quantum well active layer, and part of the first doped dielectric layer are removed to form the reflective surface.

At step S126, the light-transmitting insulating material layer located on top of the grating grooves is removed to form the grating structure, and the remaining part of the light-transmitting insulating material layer constitutes a light-transmitting insulating layer.

In the method for fabricating the laser structure in the above-mentioned embodiment, the reflective surface structure is first formed on the ridge-shaped doped dielectric layer, and then the grating structure is formed. The reflective surface and the grating structure are patterned by the same lithography pattern, so that the distance of the reflective surface from the grating structure is determined by design, and the manufacturing uncertainty is minimized. A reflective film, for example, may be deposited on the reflective surface, and the material for forming the reflective film may include high-reflection material and/or anti-reflection material, as asymmetric mirror feedback to avoid degenerate mode and achieve stable single-mode output of the laser.

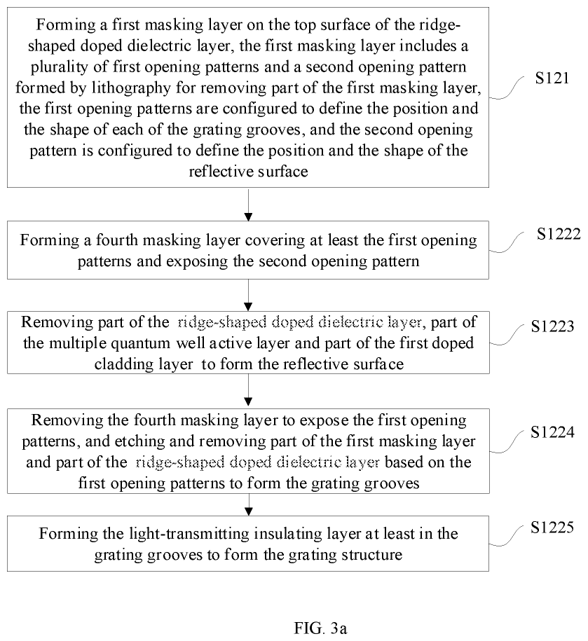

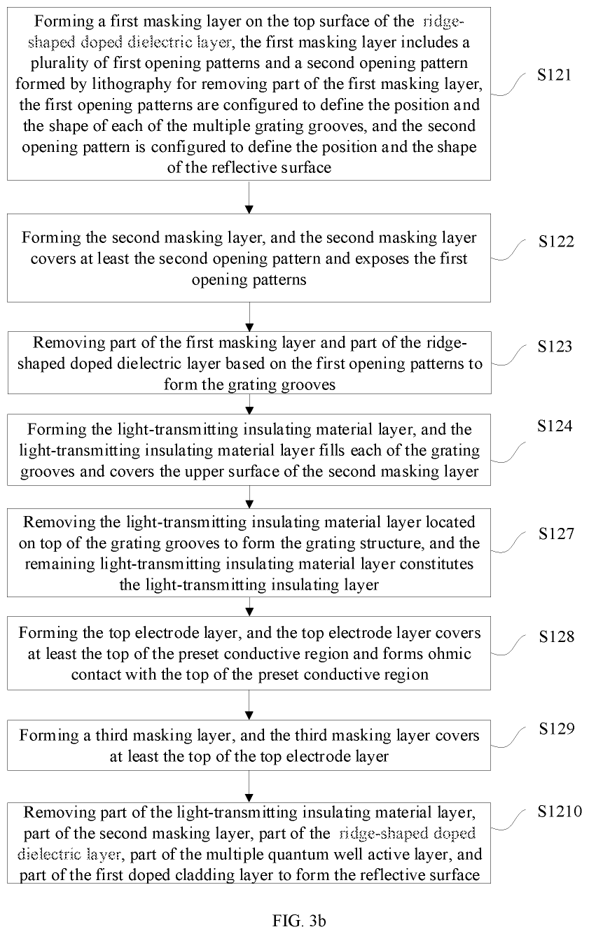

In an embodiment, referring to FIG. 3a, the steps of forming the grating structure on the ridge-shaped doped dielectric layer and forming the reflective surface on the end of the grating structure include the following steps.

At step S121, the first masking layer is formed on top of the ridge-shaped doped dielectric layer where the ridge is designed to be. The first masking layer includes the first opening patterns and the second opening pattern, the first opening patterns and the second opening pattern are formed by lithography for removing part of the first masking layer. The first opening patterns are configured to define the position and the shape of each of the grating grooves, the second opening pattern is configured to define the position and the shape of the reflective surface.

At step S1222, a fourth masking layer is formed, and the fourth masking layer covers at least the first opening patterns and exposes the second opening pattern.

At step S1223, part of the ridge-shaped doped dielectric layer, part of the multiple quantum well active layer and part of the first doped dielectric layer are removed to form the reflective surface.

At step S1224, the fourth masking layer is removed to expose the first opening patterns, and part of the first masking layer and part of the ridge-shaped doped dielectric layer are etched and removed based on the first opening patterns to form the grating grooves;

At step S1225, the light-transmitting insulating layer is formed at least in the grating grooves to form the grating structure.

In an embodiment, the first masking layer in step S121 may include a hard mask layer, and the hard mask layer may be a single-layer structure or a multi-layer stack structure, and the material of the hard mask layer includes but not limited to silicon nitride.

In an embodiment, in step S122, a deposition process may be used to form the second masking layer. The second masking layer at least covers the second opening pattern, and exposes the first opening patterns and a part of the upper surface of the ridge-shaped doped dielectric layer.

In an embodiment, in step S123, an etching process may be used to remove part of the first masking layer and part of the ridge-shaped doped dielectric layer to form the grating grooves.

In an embodiment, the preparation material of the light-transmitting insulating material layer in step S124 may include at least one of silicon nitride, silicon dioxide, silicon oxynitride, benzocyclobutene, polyimide, and spin-on glass.

In an embodiment, in step S125, an etching process may be used to remove the part of the light-transmitting insulating material, the part of the second masking layer, the part of the ridge-shaped doped dielectric layer, the part of the multiple quantum well active layer and the part of the first doped dielectric layer to form the reflective surface.

In an embodiment, in step S126, an etching process may be used to remove the light-transmitting insulating material layer on top of the grating grooves to form the grating structure, and the remaining part of the light-transmitting insulating material layer constitutes the light-transmitting insulating layer.

Specifically, referring to FIG. 2, the first masking layer simultaneously provides the first opening patterns for defining a plurality of grating grooves and the second opening pattern for defining the reflective surface, which effectively reduces the number of process steps. In addition, while reducing the process complexity and implementation cost, the accuracy of the distance between the reflection surface and the end of the grating structure is improved, so that the phase of the light reflected back to the laser cavity from the reflective surface is determined, hence the performance and stability of the laser are improved. Continue referring to FIG. 2, due to the etching rate difference of the second masking layer and the first masking layer, the second masking layer is used to protect the second opening pattern and avoid any damage on the shape of the second opening pattern when etching the grating grooves or the reflective surface.

In an embodiment, before forming the grating structure on the ridge-shaped doped dielectric layer and forming the reflective surface at one end of the grating structure, the method further includes: performing an ion implantation process on the ridge-shaped doped dielectric layer to from an electrical contact layer and form the top electrode layer on the upper surface of the electrical contact layer. The electrical contact layer enables an effective electrical connection for the top electrode layer to the preset conductive regions. Using the ion implantation process to form such the electrical contact layer on top of the ridge-shaped doped dielectric layer effectively reduces the size of the fabricated laser structure. For example, the ion implantation process may be performed from above the preset conductive regions toward the preset conductive regions to form a conductive contact layer, which makes the doping concentration of the conductive contact layer is greater than the preset conductive regions below it, so that the electrical conductivity of the conductive contact layer is better than that of the preset conductive regions below it, hence the top electrode layer can inject current downward through the conductive contact layer.

In an embodiment, referring to FIG. 3b. In an embodiment of the application, the step of forming the grating structure on the ridge-shaped doped dielectric layer, forming the top electrode layer on top of the grating structure, and forming the reflective surface on the rear side of the grating structure includes the following steps.

At step S121, the first masking layer is formed on top of the ridge-shaped doped dielectric layer, and the first masking layer includes the first opening patterns and the second opening pattern. The first opening patterns and the second opening pattern are formed by removing part of the first mask layer through single exposure lithography. The first opening patterns are configured to define the position and the shape of each of the grating grooves, and the second opening pattern is configured to define the position and the shape of the reflective surface.

At step S122, the second masking layer is formed, and the second masking layer covers at least the second opening pattern and exposes the first opening patterns.

At step S123, part of the first masking layer and part of the ridge-shaped doped dielectric layer are removed based on the first opening patterns to form the grating grooves.

At step S124, the light-transmitting insulating material layer is formed, and the light-transmitting insulating material layer fills each of the grating grooves and covers the upper surface of the second masking layer.

At step S127, the light-transmitting insulating material layer located on top of the grating grooves is removed to form the grating structure, and the remaining part of the light-transmitting insulating material layer constitutes the light-transmitting insulating layer.

At step S128, the top electrode layer is formed, and the top electrode layer covers at least the top of the preset conductive regions and forms ohmic contacts with the top of the preset conductive regions.

At step S129, a third masking layer is formed, and the third masking layer covers at least the top of the top electrode layer.

At step S1210, part of the light-transmitting insulating material layer, part of the second masking layer, part of the ridge-shaped doped dielectric layer, part of the multiple quantum well active layer, and part of the first doped dielectric layer are removed to form the reflective surface.

Please continue to refer to FIGS. 3a and 3b, the first masking layer simultaneously provides the first opening patterns for defining the plurality of grating grooves and the second opening pattern for defining the reflective surface, which effectively reduces the number of process steps. In addition, while reducing the process complexity and implementation cost, the accuracy of the distance between the reflective surface and the end of the grating structure is improved, so that the phase of the light reflected back to the laser cavity from the reflective surface is determined, hence the performance and stability of the laser are improved. The second masking layer may be provided with a different etching rate than the first masking layer, and the second masking layer is used to protect the second opening pattern and avoid any damage on the shape of the second opening pattern when etching the grating grooves.

In an embodiment, referring to FIGS. 4-9, an epitaxial structure 1000 includes a substrate 100, a first doped dielectric layer 10, a multiple quantum well active layer 20 and a ridge-shaped doped dielectric layer 30, which are stacked in sequence. The medium layer 30 is subjected to an ion implantation process, and an electrical contact layer 70 is formed on the top of the ridge-shaped doped dielectric layer 30 to form a top electrode layer 50 on the upper surface of the electrical contact layer 70. A first masking layer 80 is formed on the upper surface of the ridge-shaped doped dielectric layer 30. The first masking layer 80 includes first opening patterns 81 and a second opening pattern 82, the first opening patterns 81 and the second opening pattern 82 are formed by removing part of the first mask layer 80 through single exposure lithography. The first opening patterns 81 are configured to define the position and shape of each of the plurality of grating grooves 41, and the second opening pattern 82 is configured to define the position and shape of a reflective surface 31. A second mask layer 90 is formed, and the second mask layer 90 covers at least the second opening pattern 82 and exposes the first opening patterns 81 and part of the upper surface of the ridge-shaped doped dielectric layer 30. Part of the first masking layer 80 and part of the ridge-shaped doped dielectric layer 30 are removed to form the grating grooves 41. A light-transmitting insulating material layer 1011 is formed, and the light-transmitting insulating material layer 1011 fills each grating groove 41, and covers the upper surface of the second masking layer 90. Part of the light-transmitting insulating material 1011, part of the second masking layer 90, part of the ridge-shaped doped dielectric layer 30, part of the multiple quantum well active layer 20 and part of the first doped dielectric layer 10 are removed to form the reflective surface 31. The light-transmitting insulating material layer 1011 on top of the grating grooves is removed to form a grating structure 40, and the remaining part of the light-transmitting insulating material layer 1011 constitutes a light-transmitting insulating layer 101. The first masking layer 80 simultaneously sets the first opening patterns to define the plurality of grating grooves 41 and the second opening pattern to define the reflective surface 31, which effectively reduces the process steps, reduces the process complexity and implementation cost, and improves the accuracy of the distance between the reflective surface 31 and the end of the grating structure 40, so that the phase of the light reflected back to the laser cavity from the reflective surface is determined, and the performance and stability of the laser are improved.

In an embodiment, referring to FIGS. 4-12, the epitaxial structure 1000 includes the substrate 100, the first doped dielectric layer 10, the multiple quantum well active layer 20 and the ridge-shaped doped dielectric layer 30, stacked in sequence. The ridge-shaped doped dielectric layer 30 is subjected to an ion implantation process, and a heavily doped electrical contact layer 70 is formed on the top of the ridge-shaped doped dielectric layer 30, thus the doping concentration of the electrical contact layer 70 is greater than the doping concentration of the preset conductive regions 42 below it, so that the electrical conductivity of the electrical contact layer 70 is better than that of the preset conductive regions 42. The top electrode layer 50 is formed on top of the electrical contact layer 70 to inject current downward from the top electrode layer 50 through the electrical contact layer 70. The first mask layer 80 is formed on top of the ridge-shaped doped dielectric layer 30, and the first masking layer 80 includes the first opening patterns 81 and the second opening pattern 82 which are formed by removing part of the first masking layer 80 through single exposure lithography. The first opening patterns 81 are configured to define the position and shape of each of grating grooves 41, and the second opening pattern 82 is configured to define the position and shape of the reflective surface 31. The second masking layer 90 is formed, and the second mask layer 90 covers at least the second opening pattern 82 and exposes the first opening patterns 81 and part of the upper surface of the ridge-shaped doped dielectric layer 30. Part of the first masking layer 80 and part of the ridge-shaped doped dielectric layer 30 are removed to form the grating grooves 41. The light-transmitting insulating material layer 1011 is formed. The light-transmitting insulating material layer 1011 fills each grating groove 41, and covers the upper surface of the second masking layer 90. The light-transmitting insulating material layer 1011 located on top of the grating grooves 41 are removed to form the grating structure 40, and the remaining part of the light-transmitting insulating material layer 1011 constitutes the light-transmitting insulating layer 101. The top electrode layer 50 is formed, and the top electrode layer 50 at least covers the top of the preset conductive regions 42 and forming ohmic contacts with the preset conductive regions 42. A third masking layer 102 is formed to cover at least the upper surface of the top electrode layer 50. Part of the light-transmitting insulating material layer 1011, part of the second masking layer 90, part of the ridge-shaped doped dielectric layer 30, part of the multiple quantum well active layer 20 and the first doped dielectric layer 10 are removed to form the reflective surface 31. Since the first masking layer 80 simultaneously sets the first opening patterns 81 to define the plurality of grating trenches 41 and the second opening pattern 82 to define the reflective surface 31, the process steps are effectively reduced. In addition, while reducing the process complexity and implementation cost, the accuracy of the distance between the reflective surface 31 and the end of the grating structure 40 is improved, so that the phase of the light reflected back to the laser cavity from the reflective surface is determined, which improves the performance and stability of the laser. By choosing different etching rates for the second masking layer 90 and the first masking layer 80, and using the second masking layer 90 to protect the second opening pattern 82, any damage on the shape of the second opening pattern 82 can be avoided when etching the grating grooves 41.

In an embodiment, referring to FIGS. 4-12, before the grating structure 40 and the reflective surface 31 are formed, or in between the grating structure 40 and the reflective surface 31 are formed, or after the grating structure 40 and the reflective surface 31 are formed, the method further includes: performing at least one laser waveguide defining process on the obtained structure to further improve the performance of the laser while reducing the complexity of the production process.

In an embodiment, referring to FIGS. 4 to 12, the doping type of the first doped dielectric layer 10 is P-type, and the doping type of the ridge-shaped doped dielectric layer 30 is N-type. Alternatively, the doping type of the first doped dielectric layer 10 is N-type, and the doping type of the ridge-shaped doped dielectric layer is P-type.

In an embodiment, referring to FIGS. 4-12, the light-transmitting insulating layer 101 includes a dielectric material and/or a polymer material, therefore the light-transmitting property of the grating grooves 41 are ensured while ensuring the electrical insulating property of the grating grooves 41. The light-transmitting insulating layer may include any one of, but not limited to, silicon nitride, silicon dioxide, silicon oxynitride, benzocyclobutene, polyimide, and spin-on glass. When the grating grooves are being filled, a small amount of air, photoresist or metal may remain in the grooves, which will not seriously affect the function of the grating. Therefore, the light-transmitting insulating layer may include at least one of voids, residual photoresist and residual metal, which may increase the insulating properties of the light-transmitting insulating layer.

In an embodiment, referring to FIGS. 4-12, the material for forming the reflective surface 31 includes a high-reflection film and/or an anti-reflection film, to break the degenerate mode with asymmetric mirror feedback, and realize stable single-mode output of the laser.

In an embodiment, referring to FIG. 13, the application provides a laser structure, which is fabricated by using any of the methods for fabricating a laser structure described in the embodiments of the application. The laser structure includes the substrate 100, the first doped dielectric layer 10, the multiple quantum well active layer 20, the ridge-shaped doped dielectric layer 30, the grating structure 40 formed on the ridge-shaped doped dielectric layer 30, and the top electrode layer 50 located on top of the grating structure 40, stacked in sequence. The grating structure 40 includes a plurality of grating grooves 41 periodically spaced along the waveguide direction of the laser and the preset conductive regions 42 defined by the grating grooves 41. The light-transmitting insulating layer 101 at least covering the sidewall of the grating grooves are formed in the grating grooves. The top electrode layer 50 is at least in contact with the top of the preset conductive regions 42. The carriers injected through the surface electrode layer 50 flow through the preset conductive regions 42 and the bottom of the grating grooves 41, and then laterally diffused to the multiple quantum well active layer 20 to form a carrier distribution region providing pumping.

In an embodiment, referring to FIG. 13, the grating structure 40 formed on the ridge-shaped doped dielectric layer 30 consisting of plurality of grating grooves 41 distributed at periodic intervals (e.g., uniform intervals) along the waveguide direction of the laser and the preset conductive regions 42 defined by the grating grooves 41. Utilizing the characteristics of the small distance between the bottom of the grating grooves 41 and the multiple quantum well active layer 20, the diffusion of the injection current is limited, so that in the direction of the laser cavity, the load of the carrier density fluctuates periodically with the grating grooves 41, resulting in a certain degree of gain modulation. Since the phase of the gain coupling in the present application coincides with the phase of the index coupling, the phase of the gain coupling and the phase of the index coupling will not cancel each other out, and the intensity of the gain modulation and the refractive index modulation can be tailored by the shape, size and number of the grating grooves 41 to effectively improve the laser performance, reduce its manufacturing cost, and improve its yield and reliability.

In an embodiment, referring to FIG. 13, the shape, size and number of the grating grooves 41 may be set. So that under different injection currents, the carriers injected through the top electrode layer 50 sequentially flow through the preset conductive regions 42 to the bottom of the grating grooves 41 and laterally diffused to the multiple quantum well active layer 20, therefore a uniform carrier distribution area is formed to provide uniform carriers for pumping for the laser, which effectively improves the performance and stability of the laser. For example, the shape of the longitudinal section of the grating grooves 41 along the direction perpendicular to the laser waveguide may be set to be at least one of a rectangle, a groove, and an inverted trapezoid.

In an embodiment, referring to FIG. 13, the grating structure 40 includes the plurality of grating grooves 41 periodically spaced along the waveguide direction of the laser and the preset conductive regions 42 defined by the grating grooves 41, in other words, the distribution of the grating grooves 41 is periodic. Therefore, the grating duty cycle of the grating structure 40 is related to the gain modulation intensity of the ridge laser structure. A grating period is an average spacing between adjacent grating grooves, and the grating duty cycle is the ratio of the area of the orthographic projection of the preset conductive region 42 between adjacent grating grooves on the surface of the first doped dielectric layer 10 between the adjacent grating grooves to the grating period. The grating order of the grating structure 40 is related to the refractive index modulation intensity of the ridge laser structure.

The grating structure including a plurality of grating grooves periodically spaced along the waveguide direction of the laser and the preset conductive regions defined by the grating groove is formed on the ridge-shaped doped dielectric layer. The grating grooves are electrical insulators that limit the flow area of the injected current. When the distance between the bottom of the grating grooves and the multiple quantum well active layer is small, the diffusion of the injection current at the bottom of the grating grooves is limited, which makes the carrier density fluctuates periodically along the grating grooves in the direction of the laser cavity, producing some degree of gain modulation. Since the phase of the gain coupling in the present application coincides with the phase of the index coupling, they will not cancel each other out, and the intensity of the gain modulation and the refractive index modulation can be tailored by the shape, size and number of the grating grooves to effectively improve the laser performance. The reflective surface may be used to realize the asymmetric mirror feedback of the laser to break the degenerate mode and realize the stable single-mode output of the laser. Since the reflective surface is formed during the preparation of the grating structure, the process steps introduced by adding the reflective surface are effectively reduced, hence, reducing the manufacturing cost of the laser structure, and improving the yield and reliability.

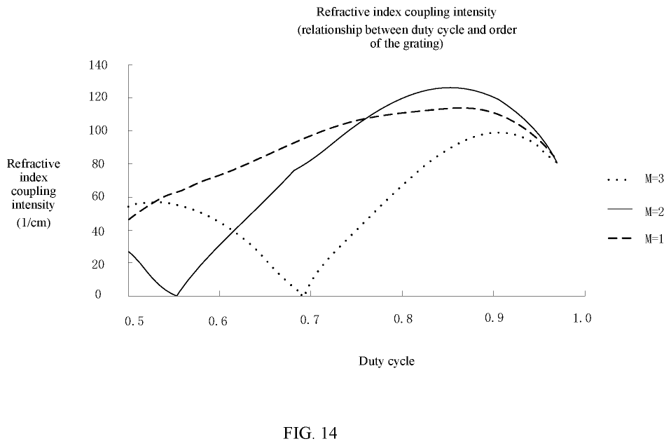

In an embodiment, referring to FIGS. 13 to 14, the corresponding relationship between the duty cycle of the grating structure 40 and the gain modulation intensity of the ridge laser structure is established, so that the gain modulation intensity of the ridge laser structure may be adjusted by setting the duty cycle of the grating structure 40. The corresponding relationship between the grating order of the grating structure 40 and the refractive index modulation intensity of the ridge laser structure is established, so that the refractive index modulation intensity of the ridge laser structure may be adjusted by setting the grating order of the grating structure 40. Thus, the degree of freedom of the gain modulation intensity and/or the refractive index modulation intensity of the fabricated laser is increased.

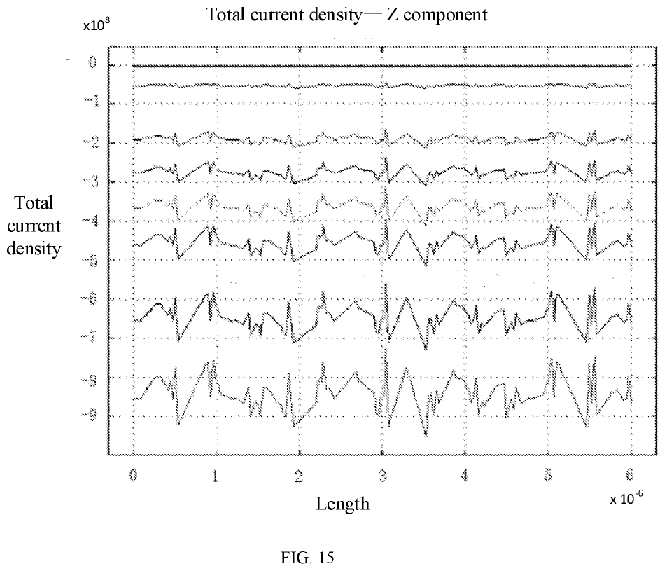

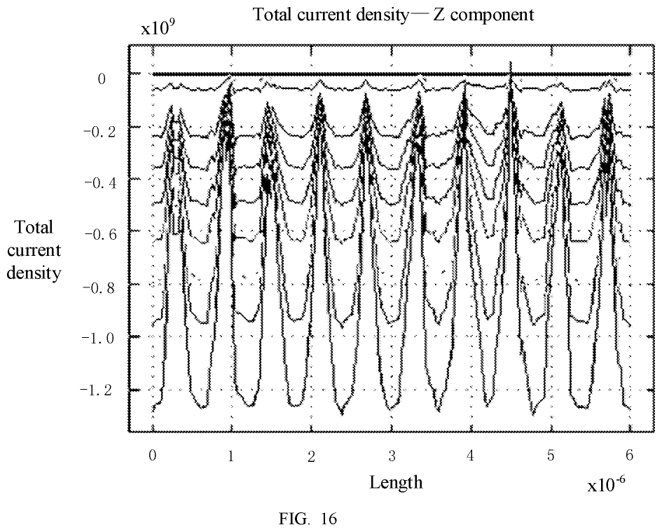

In an embodiment, referring to FIG. 13 to FIG. 16, in the case where the grating groove is formed in the ridge-shaped doped dielectric layer, the depth of the grating groove may be set to 0.6h to h, and h is the thickness of the ridge-shaped doped dielectric layer. For example, the depth of the grating grooves may be set to 0.6h, 0.8h, 0.9h or h. In this embodiment, the bottom of the grating groove is close to the multiple quantum well active layer, so that the carrier pattern formed by the current injection through the top electrode layer is well maintained under the grating groove, which modulates the carrier distribution, and in turn modulates the gain of the ridge laser structure. By comparing FIG. 15 and FIG. 16, it can be found that the higher the amplitude of the injection current, the greater the modulation degree of the carrier distribution.

It should be note that the above-described embodiments are for illustrative purposes only and are not meant to limit the application. It should be understood that the steps described are not strictly limited to the order in which they are performed, and that the steps may be performed in other orders, unless explicitly stated herein. Moreover, at least a part of the described steps may include multiple sub-steps or multiple stages. These sub-steps or stages are not necessarily executed and completed at the same time, and they may be executed at different times. The order of execution is also not necessarily sequential, they may be performed alternately or in turn with other steps or other sub-steps or at least a portion of a phase of other steps.

The various embodiments in this specification are described in a progressive manner, the focuses of each embodiment are different, and the same and similar parts between the various embodiments may be referred to each other.

The technical features of the above-described embodiments can be combined arbitrarily. In order to simplify the description, not all of the possible combinations of the technical features are described. If there is no contradiction in the combination of these technical features, they should be considered within the scope of the description in this specification.

The above-mentioned embodiments only represent several embodiments of the application, and the descriptions thereof are relatively specific and detailed, but should not be construed as limiting the scope of the patent application. For technical people skilled in the field, without departing from the concept of the present application, several modifications and improvements can be made, which all belong to the protection scope of the application. The scope of protection of the patent application shall be subject to the appended claims.

What is claimed is:

1. A method for fabricating a laser structure, comprising:
providing an epitaxial structure, the epitaxial structure comprising a substrate, a first doped dielectric layer, a multiple quantum well active layer and a ridge-shaped doped dielectric layer, which are stacked in sequence;
forming a grating structure on the ridge-shaped doped dielectric layer, and forming a reflective surface at one end of the grating structure, the grating structure comprising a plurality of grating grooves periodically spaced along a waveguide direction of the laser and preset conductive regions defined by the grating grooves, a light-transmitting insulating layer covering at least sidewall of the grating grooves being formed in each grating groove, light reflected back to a laser cavity by the reflective surface having a preset phase; and
forming a top electrode layer, the top electrode layer forming an ohmic contact with at least a top surface of each of the preset conductive regions, enabling carriers injected through the top electrode layer to flow through the preset conductive regions and the ridge-shaped doped dielectric layer under the grating grooves in turn, and then diffuse laterally to the multiple quantum well active layer to form a carrier distribution region for providing pumping.

2. The method for fabricating a laser structure according to claim 1, wherein the forming the grating structure on the ridge-shaped doped dielectric layer and forming the reflective surface at one end of the grating structure comprises:
forming a first masking layer on an upper surface of the ridge-shaped doped dielectric layer, the first masking layer comprising a plurality of first opening patterns and a second opening pattern, the first opening patters and the second opening patter being formed by removing part of the first masking layer by lithography, the first opening patterns being configured to define a position and a shape of each of the grating grooves, and the second opening pattern being configured to define a position and a shape of the reflective surface with the preset phase;
forming a second masking layer covering at least the second opening pattern and exposes the first opening patterns;
etching and removing part of the first masking layer and part of the ridge-shaped doped dielectric layer based on the first opening patterns to form the grating grooves;
forming a light-transmitting insulating material layer, the light-transmitting insulating material layer filling the grating grooves and covering an upper surface of the second mask layer;
removing part of the light-transmitting insulating material layer, part of the second masking layer, part of the ridge-shaped doped dielectric layer, part of the multiple quantum well active layer and part of the first doped dielectric layer to form the reflective surface; and
removing the light-transmitting insulating material layer located on top of the grating grooves to form the grating structure, and a remaining part of the light-transmitting insulating material layer constituting a light-transmitting insulating layer.

3. The method for fabricating a laser structure according to claim 2, Wherein after the forming the light-transmitting insulating material layer, the method further comprises:
removing the light-transmitting insulating material layer located on top of the grating grooves to form the grating structure, and the remaining part of the light-transmitting insulating material layer constituting the light-transmitting insulating layer;
forming a top electrode layer at least covering the top surface of each preset conductive region and forming the ohmic contact with each of the preset conductive region;
forming a third masking layer covering at least an upper surface of the top electrode layer; and
removing part of the light-transmitting insulating material layer, part of the second masking layer, part of the ridge-shaped doped dielectric layer, part of the multiple quantum well active layer and part of the first doped dielectric layer, to form the reflective surface.

4. The method for fabricating a laser structure according to claim 2, wherein etching rates of the second masking layer and the first masking layer are different.

5. The method for fabricating a laser structure according to claim 1, wherein the forming the grating structure on the ridge-shaped doped dielectric layer and forming the reflective surface at one end of the grating structure comprises:
forming a first masking layer on an upper surface of the ridge-shaped doped dielectric layer, the first masking layer comprising first opening patterns and a second opening pattern, the first opening patterns and the second opening pattern being formed by removing part of the first masking layer by lithography, the first opening patterns being configured define a position and a shape of each of the grating grooves, and the second opening pattern being configured to define a position and a shape of the reflective surface with the preset phase;
forming a fourth masking layer, the fourth masking layer at least covering the first opening patterns and exposing the second opening pattern;
removing part of the ridge-shaped doped dielectric layer, part of the multiple quantum well active layer and part of the first doped dielectric layer to form the reflective surface;
removing the fourth masking layer to expose the first opening patterns, etching and removing part of the first masking layer and part of the ridge-shaped doped dielectric layer based on the first opening patterns, to form the grating grooves; and
forming a light-transmitting insulating layer in at least the grating grooves to form the grating structure.

6. The method for fabricating a laser structure according to claim 5, wherein etching rates of the fourth masking layer and the first masking layer are different.

7. The method for fabricating a laser structure according to claim 1, wherein before forming the grating structure and the reflective surface, or between forming the grating structure and forming the reflective surface, or after forming the grating structure and the reflective surface, the method further comprises:
performing at least one laser waveguide defining process on an obtained structure.

8. The method for fabricating a laser structure according to claim 1, wherein after forming the reflective surface, the method further comprises:
forming a reflective film on the reflective surface, a material of the reflective film comprising at least one of high-reflection material and anti-reflection material.

9. The method for fabricating a laser structure according to claim 1, wherein the light-transmitting insulating layer comprises at least one of a dielectric material and a polymer material.

10. The method for fabricating a laser structure according to claim 1, wherein before forming the grating structure on the ridge-shaped doped dielectric layer and forming the reflective surface at one end of the grating structure, the method further comprises:
forming an electrical contact layer on the top of the ridge-shaped doped dielectric layer, and forming the top electrode layer on the top of the electrical contact layer, the electrical contact layer enables the top electrode layer to form an electrical connection with each preset conductive region.

11. A laser structure, wherein the laser structure is fabricated by:
providing an epitaxial structure, the epitaxial structure comprising a substrate, a first doped dielectric layer, a multiple quantum well active layer and a ridge-shaped doped dielectric layer, which are stacked in sequence;
forming a grating structure on the ridge-shaped doped dielectric layer, and forming a reflective surface at one end of the grating structure, the grating structure comprising a plurality of grating grooves periodically spaced along a waveguide direction of the laser and preset conductive regions defined by the grating grooves, a light-transmitting insulating layer covering at least sidewall of the grating grooves being formed in each grating groove; light reflected back to a laser cavity by the reflective surface having a preset phase; and
forming a top electrode layer, the top electrode layer forming an ohmic contact with at least a top surface of each of the preset conductive regions, enabling carriers injected through the top electrode layer to flow through the preset conductive regions and the ridge-shaped doped dielectric layer under the grating grooves in turn, and then diffuse laterally to the multiple quantum well active layer to form a carrier distribution region for providing pumping.

12. The laser structure according to claim 11, wherein the forming the grating structure on the ridge-shaped doped dielectric layer and forming the reflective surface at one end of the grating structure comprises:
forming a first masking layer on an upper surface of the ridge-shaped doped dielectric layer, the first masking layer comprising a plurality of first opening patterns and a second opening pattern, the first opening patters and the second opening patter being formed by removing part of the first masking layer by lithography, the first opening patterns being configured to define a position and a shape of each of the grating grooves, and the second opening pattern being configured to define a position and a shape of the reflective surface with the preset phase;
forming a second masking layer covering at least the second opening pattern and exposes the first opening patterns;
etching and removing part of the first masking layer and part of the ridge-shaped doped dielectric layer based on the first opening patterns to form the grating grooves;
forming a light-transmitting insulating material layer, the light-transmitting insulating material layer filling the grating grooves and covering an upper surface of the second mask layer;
removing part of the light-transmitting insulating material layer, part of the second masking layer, part of the ridge-shaped doped dielectric layer, part of the multiple quantum well active layer and part of the first doped dielectric layer to form the reflective surface; and
removing the light-transmitting insulating material layer located on top of the grating grooves to form the grating structure, and a remaining part of the light-transmitting insulating material layer constituting a light-transmitting insulating layer.

13. The laser structure according to claim 12, wherein after the forming the light-transmitting insulating material layer, the steps further comprise:
removing the light-transmitting insulating material layer located on top of the grating grooves to form the grating structure, and the remaining part of the light-transmitting insulating material layer constituting the light-transmitting insulating layer;
forming a top electrode layer at least covering the top surface of each preset conductive region and forming the ohmic contact with each of the preset conductive region;
forming a third masking layer covering at least an upper surface of the top electrode layer; and
removing part of the light-transmitting insulating material layer, part of the second masking layer, part of the ridge-shaped doped dielectric layer, part of the multiple quantum well active layer and part of the first doped dielectric layer, to form the reflective surface.

14. The laser structure according to claim 12, wherein etching rates of the second masking layer and the first masking layer are different.

15. The laser structure according to claim 11, wherein the forming the grating structure on the ridge-shaped doped dielectric layer and forming the reflective surface at one end of the grating structure comprises:
forming a first masking layer on an upper surface of the ridge-shaped doped dielectric layer, the first masking layer comprising first opening patterns and a second opening pattern, the first opening patterns and the second opening pattern being formed by removing part of the first masking layer by lithography, the first opening patterns being configured define a position and a shape of each of the grating grooves, and the second opening pattern being configured to define a position and a shape of the reflective surface with the preset phase;
forming a fourth masking layer, the fourth masking layer at least covering the first opening patterns and exposing the second opening pattern;
removing part of the ridge-shaped doped dielectric layer, part of the multiple quantum well active layer and part of the first doped dielectric layer to form the reflective surface;
removing the fourth masking layer to expose the first opening patterns, etching and removing part of the first masking layer and part of the ridge-shaped doped dielectric layer based on the first opening patterns, to form the grating grooves; and
forming a light-transmitting insulating layer in at least the grating grooves to form the grating structure.

16. The laser structure according to claim 15, wherein etching rates of the fourth masking layer and the first masking layer are different.

17. The laser structure according to claim 11, wherein before forming the grating structure and the reflective surface, or between forming the grating structure and the reflective surface, or after forming the grating structure and the reflective surface, the steps further comprise:
performing at least one laser waveguide defining process on obtained structure.

18. The laser structure according to claim 11, wherein after forming the reflective surface, the steps further comprise:
forming a reflective film on the reflective surface, a material of the reflective film comprising at least one of high-reflection material and anti-reflection material.

19. The laser structure according to claim 11, wherein the light-transmitting insulating layer comprises at least one of a dielectric material and a polymer material.

20. The laser structure according to claim 11, wherein before forming the grating structure on the ridge-shaped doped dielectric layer and forming the reflective surface at one end of the grating structure, the steps further comprise:
forming an electrical contact layer on the top of the ridge-shaped doped dielectric layer, and forming the top electrode layer on the top of the electrical contact layer, the electrical contact layer enables the top electrode layer to form an electrical connection with each preset conductive region.
